(19) United States
(12) Patent Application Publication
(10) Pub. No.: US 2003/0117223 A1
(43) Pub. Date: Jun. 26, 2003

(54) Vibrating linear actuator

(76) Inventors: Kazuhiro Shimoda, Osaka (JP); Shinichiro Kawano, Osaka (JP); Noriyoshi Nishiyama, Osaka (JP); Toshiyuki Iwahori, Tottori (JP)

Correspondence Address: RATNERPRESTIA, P O BOX 980, VALLEY FORGE, PA, 19482-0980, US

(21) Appl. No.: 10/300,478

(22) Filed: Nov. 20, 2002

(30) Foreign Application Priority Data
Nov. 22, 2001 (JP) 2001-358108

(51) Int. Cl. H03B 5/30

(52) U.S. Cl. 331/154

(57) ABSTRACT

A linear actuator includes a mover equipped with an outer yoke and a magnet, a stator equipped with coils and an inner yoke, and leaf springs for linking the movable section and the stator. The actuator is assembled such that the leaf springs are deformed when the mover stays at a balanced position. This structure can maximize a vibration stroke of the mover.

### TECHNICAL FIELD

The present invention relates to vibrating linear actuators.

### BACKGROUND ART

A vibrating paging-function is now essential to portable information devices such as cellular phones. A vibrating linear actuator is demanded because it can vibrate in a direction that users feel sensitively. At the same time, the market requires vibration generators to be thinner because the portable information devices have become slimmer and slimmer. A vibrating linear actuator equipped with a permanent magnet in a mover is the most suitable vibrating actuator to realize a compact size and a large output. However, in this vibrating linear actuator, the mover's vibration stroke becomes shorter as the body of the actuator becomes slimmer.

### DISCLOSURE OF INVENTION

The present invention addresses the foregoing problem, and aims to provide a vibrating linear actuator that can produce large vibration strokes in the thinner body.

A linear actuator of the present invention comprises the following elements:

a mover including a permanent magnet;

a stator including a coil which generates vibrating magnetic field to the mover; and

an elastic body which couples the stator to the mover.

The elastic body is assembled to the actuator such that the elastic body is deformed when the mover stays at a balanced position. This structure allows the mover to vibrate in full stroke between the upper and the lower faces of the stator, and thus maximizes the vibration stroke.

### BRIEF DESCRIPTION OF THE DRAWINGS

FIG. 1A shows a sectional view of a vibrating linear actuator in accordance with an exemplary embodiment of the present invention.

FIG. 1B shows a bottom view of the vibrating linear actuator shown in FIG. 1A.

FIG. 2A shows a bottom view of a base of the vibrating linear actuator in accordance with the exemplary embodiment of the present invention.

FIG. 2B shows a perspective view of the base of the vibrating linear actuator shown in FIG. 2A.

FIG. 3A shows a top view of a circuit board to which a vibrating linear actuator is provided.

FIG. 3B shows a lateral view of the circuit board shown in FIG. 3A.

FIG. 4 shows a cellular phone employing the vibrating linear actuator in accordance with the exemplary embodiment of the present invention.

FIG. 5 shows a sectional view of a vibrating linear actuator of which outer yoke is ready to be mounted with a leaf spring.

FIG. 6 shows a sectional view of a vibrating linear actuator of which mover arrives at a top dead center.

FIG. 7 shows a sectional view of a vibrating linear actuator of which mover arrives at a bottom dead center.

FIGS. 8A, 8B, and 8C illustrate properties of a leaf spring.

FIGS. 9A, 9B and 9C illustrate a movable area of a mover.

FIG. 10 shows a sectional view of a vibrating linear actuator in accordance with another exemplary embodiment.

### DESCRIPTION OF THE PREFERRED EMBODIMENT

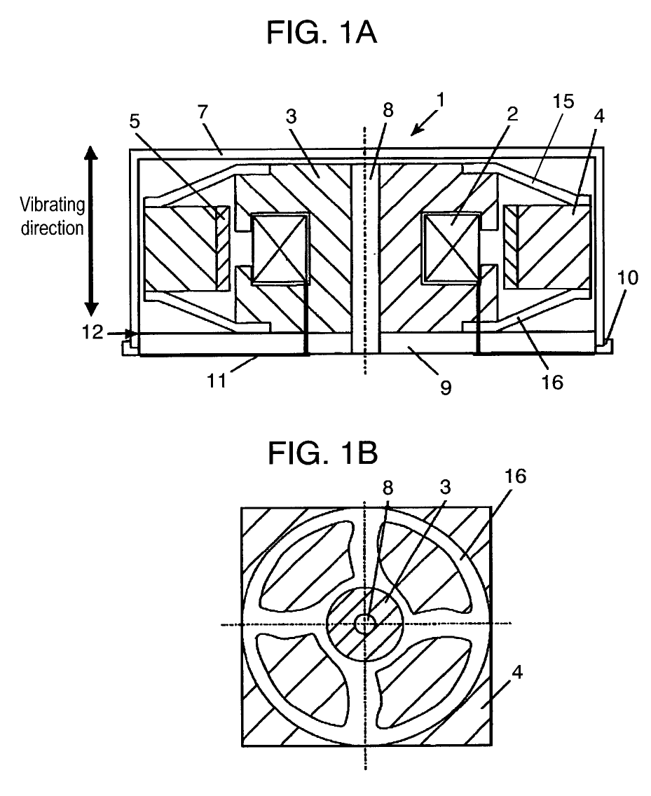

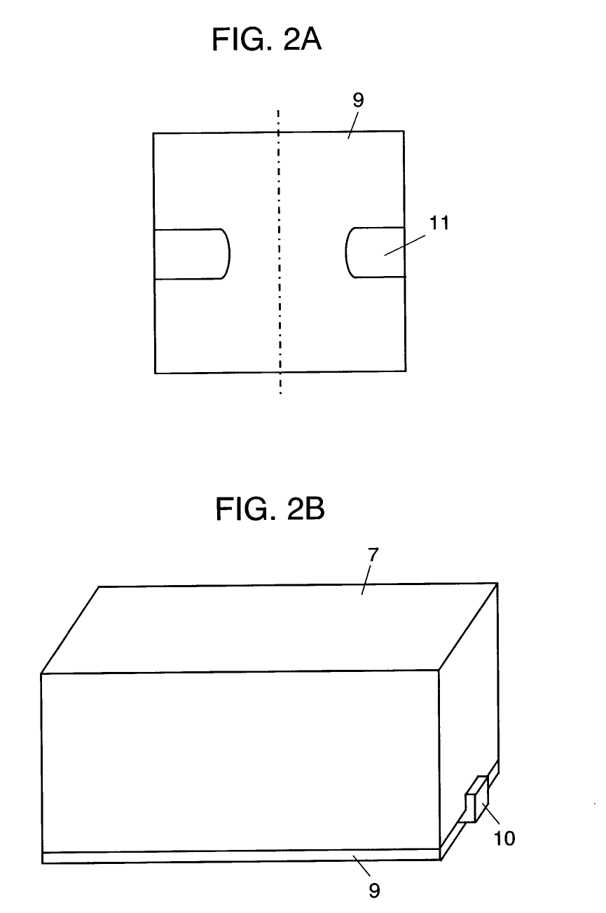

An exemplary embodiment of the present invention is demonstrated hereinafter with reference to the accompanying drawings. FIG. 1A through FIG. 2B illustrate the structure of the vibrating linear actuator (hereinafter simply referred to as an actuator) of the present invention. Actuator 1 comprises the following elements:

polygonal outer yoke 4;

cylindrical inner yoke 3 disposed inside outer yoke 4;

coil 2 wound on inner yoke 3; and

magnet 5 provided to outer yoke 4 such that magnet 5 faces to inner yoke 3.

Inner yoke 3 and outer yoke 4 are made from metallic substance formed of green compact of magnetic powder. They can be formed by laminating steal sheets radially on shaft 8. Inner yoke 3 and coil 2 form a stator, and outer yoke 4 and magnet 5 form a mover.

Inner yoke 3 holds shaft 8 at the center of yoke 3, and a first end of shaft 8 extends through a bottom face of inner yoke 3. Inner yoke 3 is positioned by the extruding portion of shaft 8 and a recess of base 9 and rigidly mounted on base 9. Lower leaf spring 16 is inserted between base 9 and inner yoke 3. Base 9 is made from heat-resistant resin of which glass transition temperature is not less than 90° C. Upper leaf spring 15 is mounted to an upper section of inner yoke 3.

FIG. 1B shows a bottom face of actuator 1. Lower leaf spring 16 is formed of a ring-shaped leaf spring, and comprises the following elements:

a ring-shaped inner rim for fixing on inner yoke 3;

a ring-shaped outer rim for fixing on outer yoke 4; and

radial extension section for linking the inner rim to the outer rim.

Coil 2 is electrically coupled to metal land 11 extending from the bottom of base 9, and powered by land 11. Lid 7 covers inner yoke 3 and outer yoke 4, and is caulked to base 9 with lid-caulking section 10 provided to base 9. Lid 7 protects the actuator from outside air or against damages when the actuator undergoes reflow soldering. Lid 7 also helps handling of the actuator. Lid 7 is made from metal; however, it can be made from heat-resistant resin.

Actuator 1 flows the current supplied from land 11 to coil 2, thereby generating vibrating magnetic flux. This vibrating magnetic flux drives outer yoke 4 to vibrate up and down as indicated with an arrow mark in FIG. 1.

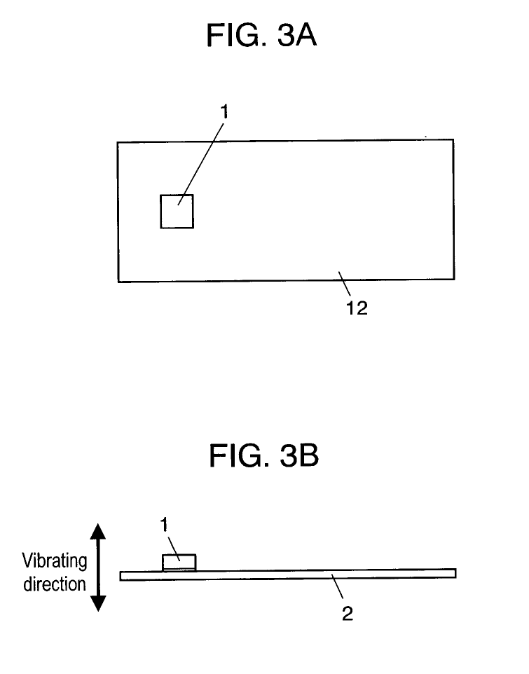

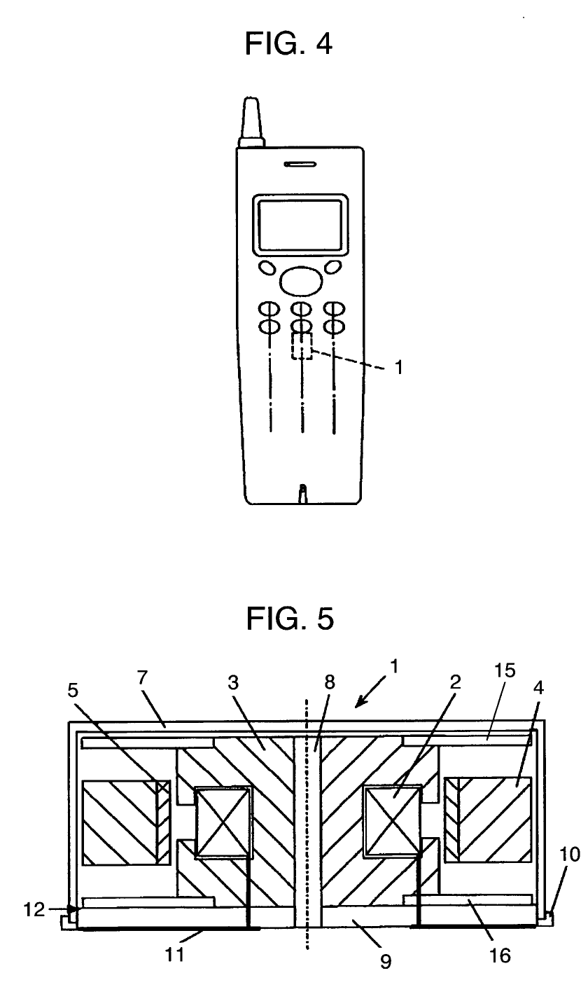

FIG. 2A shows a bottom of base 9, and land 11 is exposed from the base. FIG. 2B shows a perspective view of the actuator covered with lid 7. FIG. 3A and FIG. 3B show an actuator mounted on circuit board 12 of a cellular phone shown in FIG. 4. Circuit board 12 is a multi-layered and double-sided board, and electronic components other than the actuator are mounted; however, they are omitted in FIGS. 3A and 3B. Land 11 of the actuator is reflow-soldered to a land (not shown) of circuit board 12. A motor driving circuit (not shown) on circuit board 12 powers coil 2 via land 11, thereby regulating the vibration of the actuator.

FIG. 5 shows a sectional view of actuator 1 of which outer yoke is now ready to be mounted with a leaf spring. Upper leaf spring 15 is fixed to the upper face of inner yoke 3 at its first end, and lower leaf spring is fixed to the lower face of inner yoke 3 at its first end. The second ends of both the leaf springs are free. Both the springs extend like a flat plate free from deformation. From this status, upper leaf spring 15 is deformed downward and its second end is fixed to the upper face of outer yoke 4, and lower leaf spring 16 is deformed upward and its second end is fixed to the lower face of outer yoke 4. Actuator 1 shown in FIG. 1A is thus realized. The mover formed of magnet 5 and outer yoke 4 halts at a balanced position as shown in FIG. 1A when current does not run through coil 2 (i.e. at free status). At this time, upper leaf spring 15 is deformed downward, and lower leaf spring 16 is deformed upward.

An elastic body, such as a leaf spring, for linking a stator to a mover is deformed when the mover stays at a balancing position. This is a feature of the present invention. In this status, leaf spring 15 generates upward thrust force, and leaf spring 16 generates downward thrust force, so that both the springs attract each other.

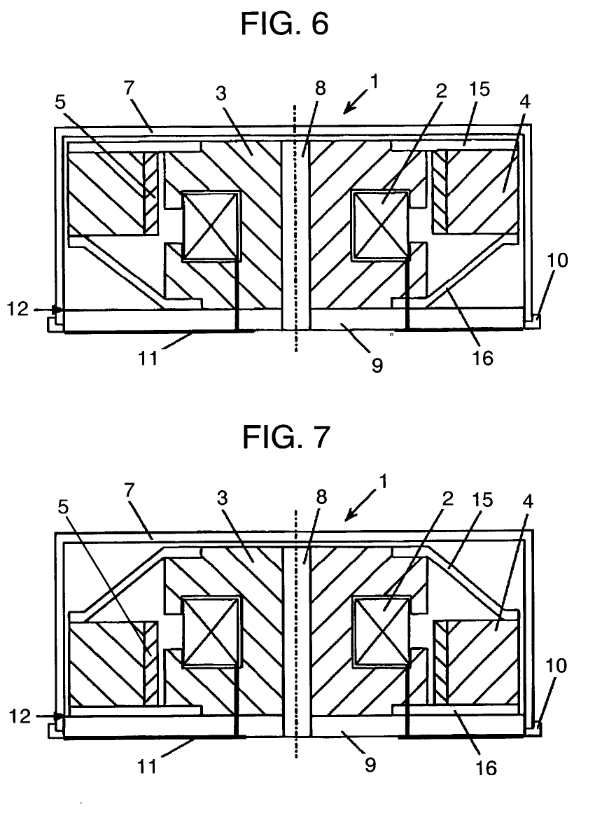

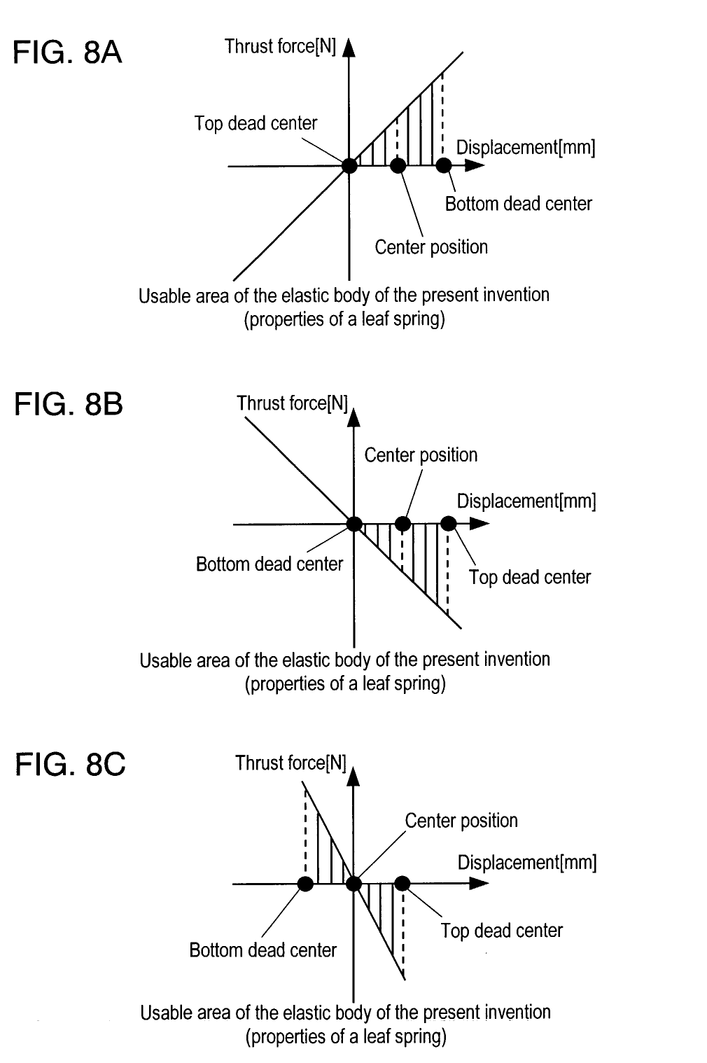

When coil 2 is powered, as shown in FIG. 6, the mover reaches a top dead center where the upper face of the mover is nearly flush with the upper face of inner yoke 3. At the top dead center, upper leaf spring 15 extends like a flat plate, and spring 16 largely becomes deformed upward. When a polarity of the current running through coil 2 is inverted, as shown in FIG. 7, the mover reaches the bottom dead center where the lower face of the mover is nearly flush with the lower face of inner yoke 3. At the bottom dead center, lower leaf spring 16 extends like a flat plate, and spring 15 largely becomes deformed downward. FIG. 8A shows a relation between displacement of the mover and the thrust force of upper leaf spring 15. Between the top and bottom dead centers, upper spring 15 becomes deformed downward and produces upward thrust force. FIG. 8B shows a relation between the displacement of the mover and the thrust force of lower leaf spring 16. Between the top and bottom dead centers, lower spring 16 becomes deformed upward and produces downward thrust force. FIG. 8C shows a relation between the displacement of the mover and the totaled thrust force of both the leaf springs. The totaled thrust force varies linearly between the top and bottom dead centers. FIG. 8C teaches that the mover vibrates smoothly between the top dead center and the bottom dead center.

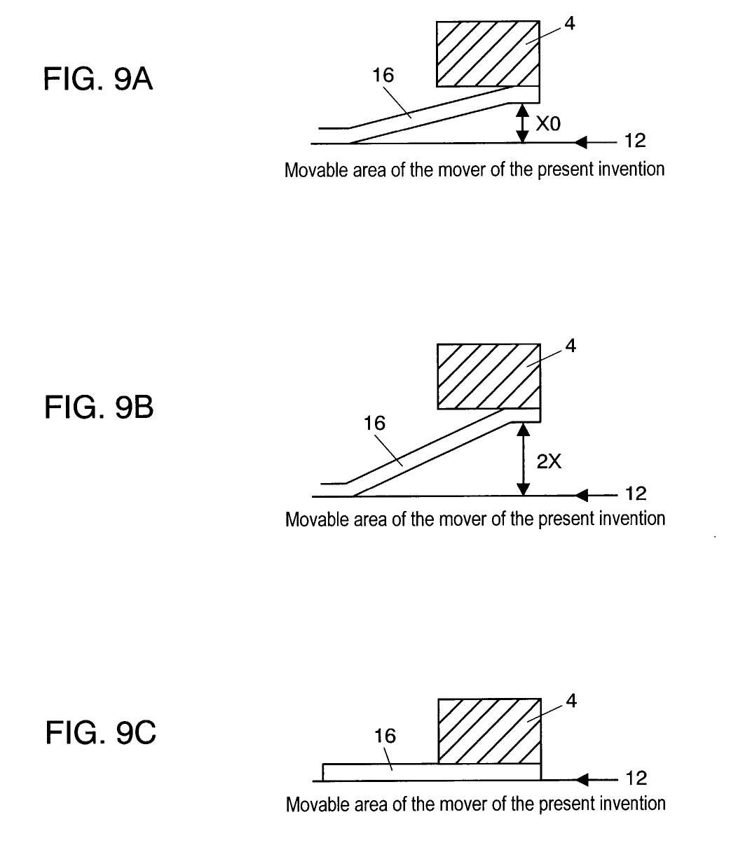

FIG. 9A through FIG. 9C illustrate a movable area of lower leaf spring 16 and the mover. At the bottom dead center, lower leaf spring 16 restores to the flat-plate status, so that the mover allows vibrating in greater strokes.

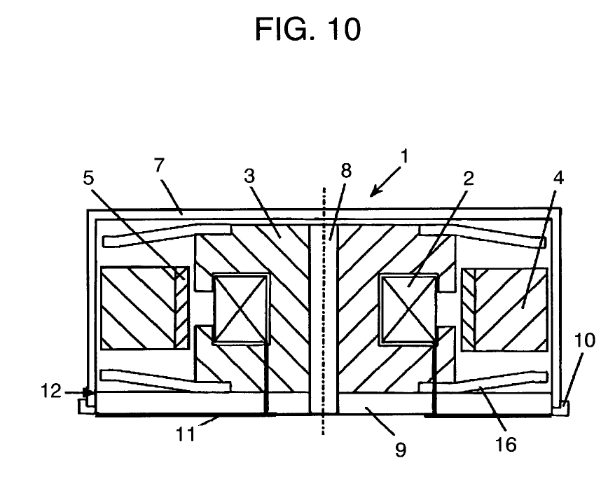

As shown in FIG. 10, the leaf spring can be bowed before it is mounted to outer yoke 4.

As discussed above, in the vibrating linear actuator of the present invention, the elastic body, such as a leaf spring, for linking the stator to the mover is assembled to the actuator such that the elastic body is deformed when the mover is at a balanced position. This structure allows the mover to vibrate in a full stroke between the upper and lower faces of the stator. As a result, the stroke of vibrations can be maximized. Meanwhile, a length of the mover in a thrust direction is shorter than a length of the stator in a thrust direction.

What is claimed is:

1. A vibrating linear actuator comprising:
a mover including a permanent magnet;
a stator including a coil which generates a vibrating magnetic field that vibrates said mover; and
an elastic body, for linking said stator to said mover and being assembled to the actuator such that said elastic body is deformed when said mover stays at a balanced position.

2. The actuator of claim 1, wherein a length of said mover in a mover thrust direction is shorter than a length of said stator in a stator thrust direction.

3. The actuator of claim 1, wherein said elastic body is a leaf spring to be mounted to an end, in said stator thrust direction, of said stator.

4. The actuator of claim 3, wherein the leaf spring includes an upper leaf spring and a lower leaf spring, and both the upper and lower leaf spring attract each other when said mover stays at the balanced position.

5. The actuator of claim 1, wherein said elastic body is a leaf spring which stays like a flat plate when no load is applied.

6. The actuator of claim 1, wherein said mover is covered with a base and a lid.

7. A portable information device employing a vibrating linear actuator therein, the vibrating linear actuator comprising:
a mover including a permanent magnet;
a stator including a coil which generates a vibrating magnetic field that vibrates said mover; and
an elastic body, for linking said stator to said mover and being assembled to the actuator such that said elastic body is deformed when said mover stays at a balanced position.
